(19) United States
(12) Patent Application Publication
(10) Pub. No.: US 2006/0105520 A1
(43) Pub. Date: May 18, 2006

(54) Structure and method to fabricate a protective sidewall liner for an optical mask

(76) Inventors: Sia Kim Tan, Singapore (SG); Qun Ying Lin, Singapore (SG); Liang Choo Hsia, Singapore (SG)

Correspondence Address: WILLIAM STOFFEL, PMB 455, 1735 MARKET ST. - STE. A, PHILADELPHIA, PA, 19103-7502, US

(21) Appl. No.: 10/992,447

(22) Filed: Nov. 18, 2004

(51) Int. Cl. H01L 21/8242

(52) U.S. Cl. 438/244

(57) ABSTRACT

Methods and structures for optical masks that have a liner on the trench sidewalls. An example embodiment comprises a mask structure for use with light at a wavelength comprising: a substrate having a first region, a second region and a third region; a first trench in the first region; a first region having a first thickness of a first material, the first material having a first amount of transmission of light at the wavelength, the second region having a second thickness of the first material, such that the second thickness is greater than the first thickness by a first difference, the first difference being equivalent to a phase shift of 180 degrees at the wavelength, and a third region located on the substrate, the third region having a third thickness of the first material, such that the third thickness is equal to or greater than the second thickness; a liner on the sidewalls of the trench. The liner reduces the reflections from the trench sidewall. The embodiments can be used with single and double phase shift masks and with chromeless phase lithography masks.

### BACKGROUND OF INVENTION

1) Field of the Invention

The present invention relates to the field of semiconductor integrated circuit manufacturing, and more specifically, to a phase-shifting mask and a process for fabricating a phase-shifting mask.

2) Description of the Prior Art

Improvements in photolithography have allowed higher density and faster speed to be attained in semiconductor Integrated Circuits (ICs) by continually shrinking the devices. According to the Rayleigh criterion, the minimum Critical Dimension (CD) which can be resolved by a wafer stepper is directly proportional to the wavelength of the illumination source and inversely proportional to the Numerical Aperture (NA) of the projection lens. However, diffraction will degrade the aerial image when the CD becomes smaller than the actinic wavelength. The actinic wavelength is the wavelength of light at which a mask is used in a wafer stepper to selectively expose photoresist on a substrate.

Photolithography in the sub-actinic wavelength regime will benefit from wavefront engineering with Resolution Enhancement Techniques (RETs), such as Phase-Shifting Masks (PSMs), to achieve a sufficiently wide process latitude. Unlike a conventional binary mask that only modulates the amplitude of light, a PSM further controls the phase of light to take advantage of destructive interference to mitigate the detrimental effects of diffraction. An Alternating PSM (AltPSM) is particularly useful for patterning very small CDs, such as the gate length of a transistor in a device. AltPSM improves contrast by introducing a phase shift of 180 degrees between the light transmitted through adjacent clear openings to force the amplitude between the two images to zero.

A phase shift of 180 degrees can be implemented creating a difference in the optical path lengths through adjacent openings in an opaque layer, such as chrome.

However, an AltPSM that is fabricated with a subtractive process will scatter incident light off the sidewalls and bottom corners of the etched openings. The waveguide effect causes an aerial image imbalance which is manifested as a CD error and a placement error. The CD of the etched opening becomes smaller than the CD of the unetched opening. The space between the two openings appears displaced from the unetched opening towards the etched opening.

The various approaches for balancing the aerial image have disadvantages. The CD biasing approach is constrained to the discrete values available on the design grid. The etchback approach, also know commonly as undercut, may cause defects, such as chipping or delamination of the overhanging chrome between adjacent openings. The dual-trench approach adds complexity and cost by requiring additional processing

The importance of overcoming the various deficiencies in PSMs is evidenced by the extensive technological development directed to the subject, as documented by the relevant patent and technical literature. The more relevant technical developments in the literature can be gleaned by considering the following.

Levenson, et al., “Exposing the DUV SCAAM”, Proceeding of SPIE Vol. 4692(2002) pp. 288-297.

US 2004-0 086 787 A1-Waheed, Nabila Lehachi; et al.—Alternating aperture phase shift photomask having plasma etched isotropic quartz features.

U.S. Pat. No. 6,458,495 (Tsai et al.) shows an AAPSM with trenches.

U.S. Pat. No. 6,410,191 B1 (Nistler et al.) shows a PSM.

U.S. Pat. No. 6,627,359B2 (Kokubo) shows a PSM showing trench.

U.S. Pat. No. 6,534,225B2 (Flanders et al.) shows an AAPSM.

U.S. Pat. No. 5,994,001 (Nako) shows a process for trenches for a PSM.

### SUMMARY OF THE INVENTION

The example embodiments of present invention provides a mask and method of manufacturing a PSM mask and a CPL mask having a liner on a trench sidewall.

In a first example embodiment, a method of fabricating a phase-shifting mask for use with a light at a wavelength comprises the following:
a) providing a substrate comprised of a transparent material, the substrate comprising a first region, a second region, and a third region,
b) forming an opaque pattern over the third region of the substrate;
c) using a trench etch to form a first trench in the first region, the trench having sidewalls and a trench bottom; the first trench extends a first undercut distance under the opaque pattern;
d) forming a liner over the sidewalls of the first trench;
   whereby the light at the wavelength transmitted through the first region is shifted in phase by 180 degrees relative to the light at the wavelength transmitted through the second region;
   whereby the liner reduces reflection from the trench sidewalls.

Another embodiment is a method of fabricating a phase-shifting mask for use with a light at a wavelength that comprises the following:
providing a substrate comprised of a transparent material, the substrate having a first thickness, the substrate comprising a first region, a second region, and a third region,
forming an opaque layer over the substrate,
etching in a first etch to remove the opaque layer in the first region and the second region to form a opaque pattern on the third region,
forming a masking pattern having openings over the first region;
etching the substrate in a trench etch to form a first trench in the first region, the trench having sidewalls and a trench bottom; the first trench extends a first undercut distance under the opaque pattern;
forming a lining layer over the masking pattern and the trench;
anisotropically etching the lining layer to form a liner on the sidewalls of the trench;
removing the masking pattern; whereby the light at the wavelength transmitted through the first region is shifted in phase by 180 degrees relative to the light at the wavelength transmitted through the second region;
   whereby the liner reduces reflection from the trench sidewalls.

Another embodiment is a chromeless phase lithography mask with a opaque patch for use with light at a wavelength comprises the following:
a substrate having a first region, a second region, a third region, and forth region;
a first region trench in the first region and a second region trench in the second region; a first region and the second region having a first thickness of a first material, the first material having a first amount of transmission of light at the wavelength,
the third region and the fourth having a second thickness of the first material, such that the second thickness is greater than the first thickness by a first difference, the first difference being equivalent to a phase shift of 180 degrees at the wavelength, and
an opaque pattern over the fourth region;
a liner over the sidewalls of the first region trench and the second region trench.

The above and below advantages and features are of representative embodiments only, and are not exhaustive and/or exclusive. They are presented only to assist in understanding the invention. It should be understood that they are not representative of all the inventions defined by the claims, to be considered limitations on the invention as defined by the claims, or limitations on equivalents to the claims. For instance, some of these advantages may be mutually contradictory, in that they cannot be simultaneously present in a single embodiment. Similarly, some advantages are applicable to one aspect of the invention, and inapplicable to others. Furthermore, certain aspects of the claimed invention have not been discussed herein. However, no inference should be drawn regarding those discussed herein relative to those not discussed herein other than for purposes of space and reducing repetition. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

The features and advantages of a lithography mask according to the present invention and further details of a process of fabricating such a mask in accordance with the present invention will be more clearly understood from the following description taken in conjunction with the accompanying drawings in which like reference numerals designate similar or corresponding elements, regions and portions and in which:

FIGS. 1A through 1F are cross sectional views for illustrating a method for manufacturing a phase shift mask (PSM) according to first embodiment of the present invention.

FIGS. 2A through 2F are cross sectional views for illustrating a method for manufacturing a PSM mask according to second embodiment of the present invention.

FIGS. 3A thru 3K are cross sectional views for illustrating a method for manufacturing a PSM mask according to third embodiment of the present invention.

FIGS. 4A to 4G are cross sectional views for illustrating a method for manufacturing a double trench PSM mask according to fourth embodiment of the present invention.

FIGS. 5A to 5I are cross sectional views for illustrating a method for manufacturing a chromeless phase shift lithography (CPL) mask according to another embodiment of the present invention.

### DETAILED DESCRIPTION OF THE EXAMPLE EMBODIMENTS

In the following description, numerous details, such as specific materials, dimensions, and processes, are set forth in order to provide a thorough understanding of the present invention. However, one skilled in the art will realize that the invention may be practiced without these particular details. In other instances, well-known semiconductor equipment and processes have not been described in particular detail so as to avoid obscuring the present invention

The example embodiments of present invention describes alternating aperture phase-shifting masks (PSM) that have a liner preferably only the trench sidewalls. The liner improves the balance the transmission and phase between the phase-shifted openings and the non-phase-shifted openings. The sidewall liner blocks off stray lights. Balancing transmission and phase prevents CD error and placement error. The examples include single and double trench PSMs and Chromeless Phase Lithography (CPL) masks.

### II. First Example Method Embodiment Single Trench PSM

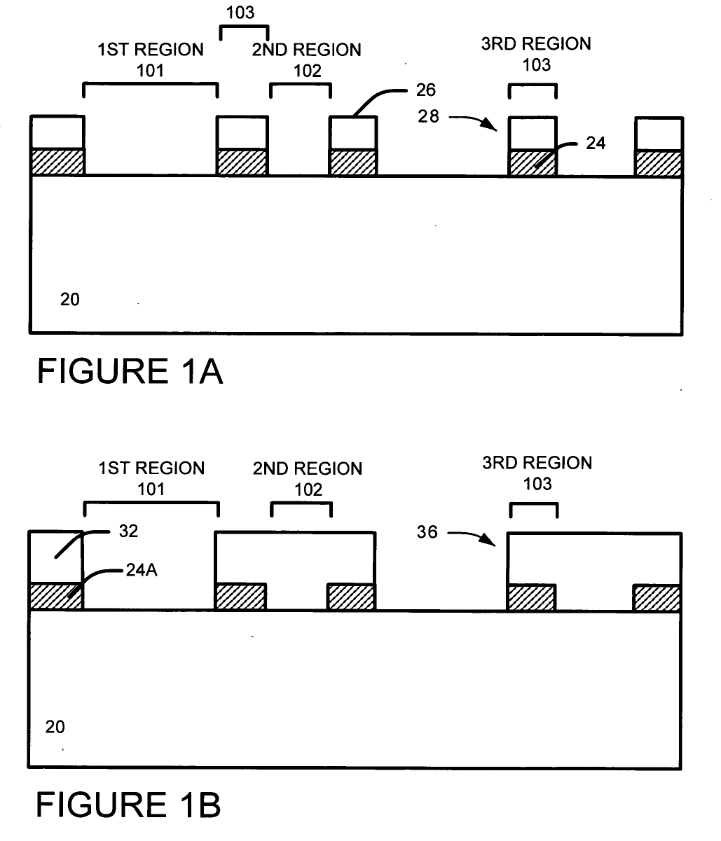

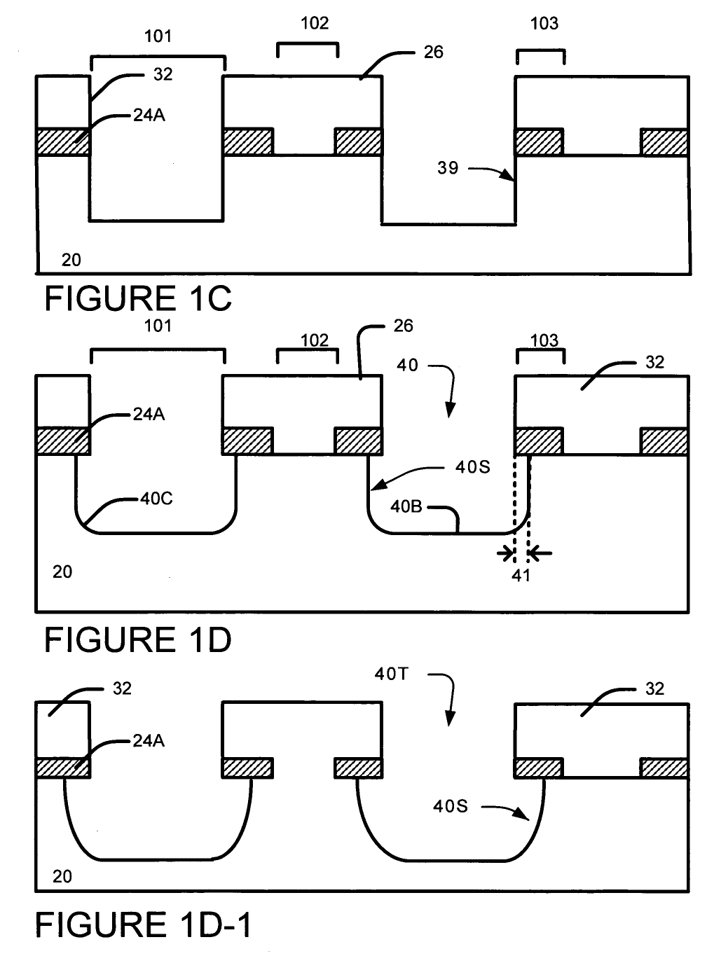

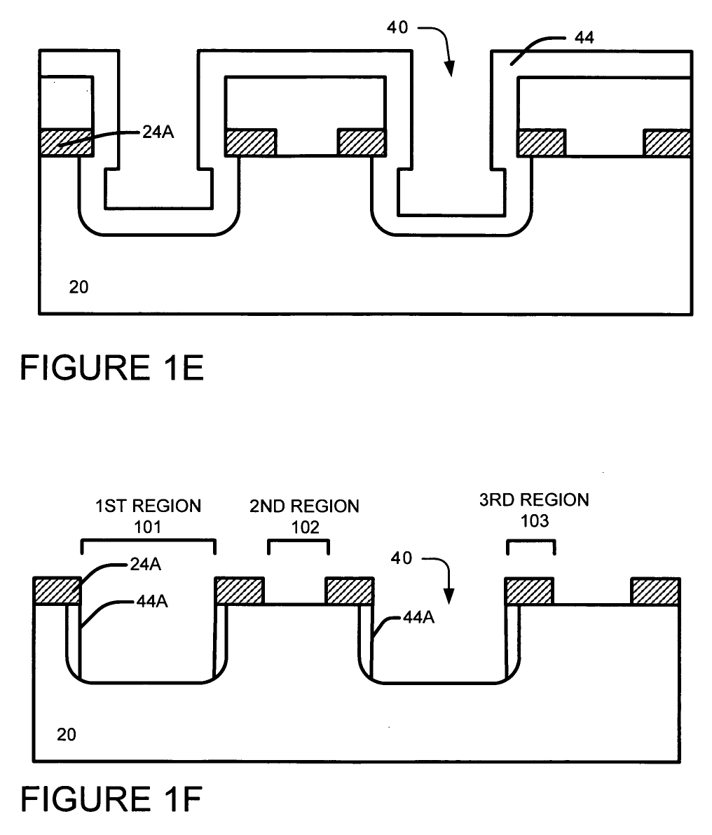

A first example method embodiment is shown in FIGS. 1A to 1F and 1D-1.

As shown in FIG. 1A, a substrate 20 comprised of a transparent material is provided. The substrate has a first thickness. The substrate 20 comprises a first region 101, a second region 102, and a third region 103. The first region will be a phase-shifted region, such as a 180 degree phase shift region. The second region will be a non-phase shifted region (e.g., 0 degree phase shift). The third region will be an opaque region.

The substrate 20 is preferably transparent to light at the actinic wavelength. Fused silica (SiO₂), also known as quartz, is commonly used at illumination wavelengths of 436 nanometers (g-line of Mercury lamp), 365 nanometers (i-line of Mercury lamp), 248 nanometers (KrF excimer laser), and 193 nanometers (ArF excimer laser).

Crystalline fluorides, such as Calcium Fluoride (CaF₂), Magnesium Fluoride (MgF₂), Barium Fluoride (BaF₂), and Lithium Fluoride (LiF₂), are transparent at the illumination wavelength of 157 nanometers (F₂ excimer laser), but they have excessively large coefficients of thermal expansion and poor chemical etch resistance. Consequently, modified fused silica, such as low water (—OH) content-fused silica and fluorine (F₂)-doped silica, are more suitable for use as substrates for transmissive masks at 157 nanometers.

We form an opaque layer 24 over the substrate 20. The opaque layer is preferably comprised of chrome.

The opaque layer 24 typically is comprised of chrome of sufficient thickness to be opaque. The layer 24 is formed from Chromium (Cr), usually in a graded or multilayer structure. Oxygen (O) and Nitrogen (N) are included towards the upper surface to reduce reflection when the mask is used in a wafer stepper. Oxygen (O) is included towards the lower surface to improve adhesion to the substrate. The layer may also be formed from refractory metals, such as Tungsten (W), Tantalum (Ta), metal silicides, such as Molybdenum Silicide (MoSi), metal nitrides, such as Tungsten Nitride (WN), Tantalum Nitride(TaN), amorphous Silicon (Si), or amorphous Carbon (C).

A first masking pattern 26 is formed over the opaque layer 24. The first masking pattern 26 has openings 28 over the first and second regions. The first masking pattern is preferably a resist layer that is patterned using an ebeam or laser writes, develop and etch process.

As shown in FIG. 1B, we use a first etch to remove the opaque layer in the first region 101 and the second region 103. Chrome may be etched with a wet etch. The wet etch may include Ceric Ammonium Nitrate ((NH₄)₂ Ce(NO₃)₆) with an oxidizing agent, such as nitric acid, acetic acid, or perchloric acid.

The first resist layer 26 is them removed.

As shown, in FIG. 1B, we form a masking pattern 32 having openings 36 over the first region 101. The first masking pattern is preferably a resist layer that is patterned using an ebeam or laser write, develop and etch process.

A. Trench Undercut

As shown in FIGS. 1C and 1D, we use a trench etch process to form a trench (39 or 40) in the first region. The trench 40 has sidewalls 40S and a trench bottom; 40B and trench corner 40C.

The trench etch process is preferably comprised of (FIG. 1C) an anisotropic etch and (FIG. 1D) an isotropic etch. FIG. 1C shows first vertical sidewall trench 39 after the anisotropic etch. FIG. 1D shows the rounded corner trench 40 after the isotropic etch.

At the current technology dimensions, the trench preferably has an undercut (side etching dimension) 41 under the opaque layer by about between 20 and 50 nm. That is the trench preferably extends under the opaque layer by between 20 and 50 nm

The undercut distance 41 is preferably equal or less than 50% of the minimum opaque layer width. But the distance is preferably subjected to the minimum bonding area of the opaque layer to the quartz so that delimitation of the opaque layer do not occur during the mask making processes. The distance should also depth enough so that the light can be absorbed by the liner material used, which depends on the liner optical property, mainly the extinction coefficient. The larger the extinction coefficient, the less undercut distance is needed.

The final depth of the trench corresponds to a difference in the optical path length through the transparent substrate 20 between the phase-shifted opening 101 and the non-phase-shifted opening 102. A phase shift of 180 degrees is desired. The tolerance should be tighter than +/−2 degrees. The depth of the trench has about the same magnitude of the illumination wavelength when the transparent substrate is quartz and the ambient is air.

In one option, the sidewall of the trench is preferably mostly straight preferably within 2 degrees of vertical slope. The bottom surface of the etched trench is preferably flat and smooth, The bottom corners of the etched trench may be rounded. Deviations and non-uniformities in the size and shape of the trench will introduce errors in transmission and phase.

The trench sidewall can have other shapes that the about vertical shape. For example, FIG. 1D-1 shows the sidewall 40T has a curve profile. Depending on the etch depth and the amount of undercuts, the sidewall profile may be curve in shape instead of the vertical shape.

B. Lining Layer

As shown in FIG. 1E, we form a lining layer 44 over the masking pattern 32 and the trench.

The lining layer preferably has a thickness within 10% of the distance of the undercut 41 and more preferably within 5% of the distance of the undercut 41.

The lining layer 44 is preferably comprised of a materials that with high extinction coefficient between about 1.0 and 3.0.

The lining layer 44 is preferably comprised of a material with a reflective index between 1.4 and 1.6.

The lining layer 44 is comprised of a material with a reflective index within 5% of the reflective index of quartz. For example, a reflective index within 5% of the reflective index of quartz is about 1.5 at wavelength of 193 nm to 248 nm.

The lining layer 44 is preferably comprised of a materials with etch selective to chromium and quartz of between 0.01 and 0.1.

The lining layer 44 is preferably comprised of a metal, such as molybdenum, aluminum, gold; and its metal compound. Compound for example: metal oxides, (such as molybdenum oxide, aluminum oxide; or a metal nitrate, such as aluminum nitrate; or metal silicide or silicon and its compounds such as silicon oxynitride.

The liner is a not preferably comprised of chrome. This is because during the etching process of the liner shown in FIG. 1F, if other material other than chrome is used, the chrome (24A) could be used as a hard mask to resist the etch reaction and the liner in the trench (40) can still be etched away. In addition, the reflective index of Chrome is at a value of about 0.85 compared to quartz of about 1.5. Most of the light travelling from the quartz (the mask is inverted during the photolithography process) will be reflected back into the quartz, at the quartz to chrome boundary. Thus creating undesired interference inside the quartz.

The resultant mask has a sidewall liner 44A underneath the chrome 24A to block off stray lights.

C. Form Liner

As shown in FIG. 1F, we anisotropically etch the lining layer 44 to form a liner 44A on the sidewalls of the trench 40. The liner 44A is preferably formed only on the sidewalls of the trench and is preferably not formed over the chrome 24A or the bottom of the trench. The opaque pattern acts as a hard mask.

Next, we remove the masking pattern 32.

Light at the wavelength is transmitted through the first region 101 is preferably shifted in phase by 180 degrees relative to the light at the wavelength transmitted through the second region 102.

Some non-limiting example benefits are:
Dry etch defects (e.g., FIG. 1C) are eliminated by wet etching processes of trench.
Trench surface is less rough after wet etching.
Chrome dimension can more correctly controlled.
Overhanging chrome, as a result of undercuts, is supported by the liner to prevent removal during mask cleaning.

### III. Second Example Embodiment—PSM

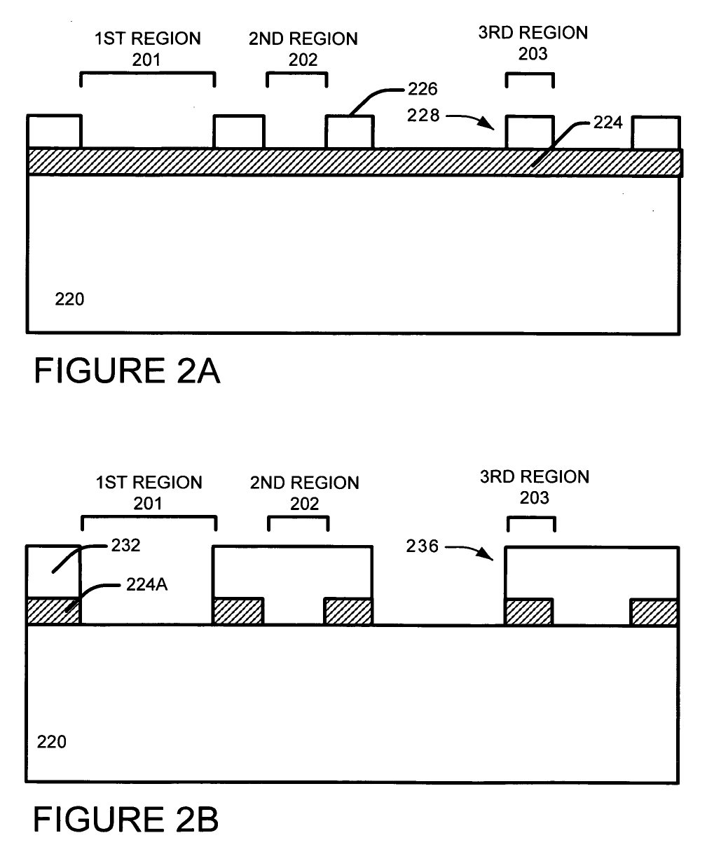

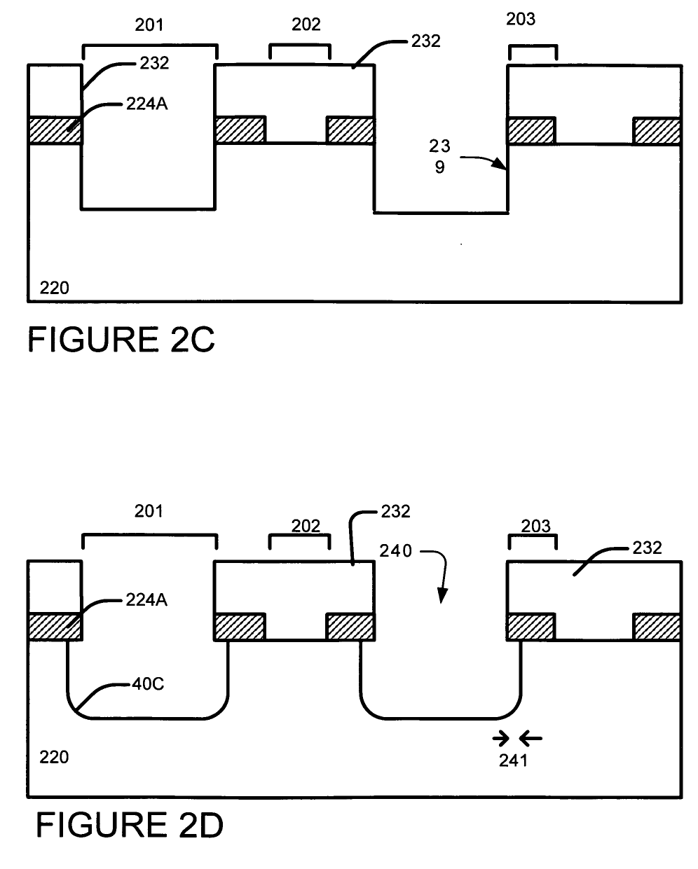

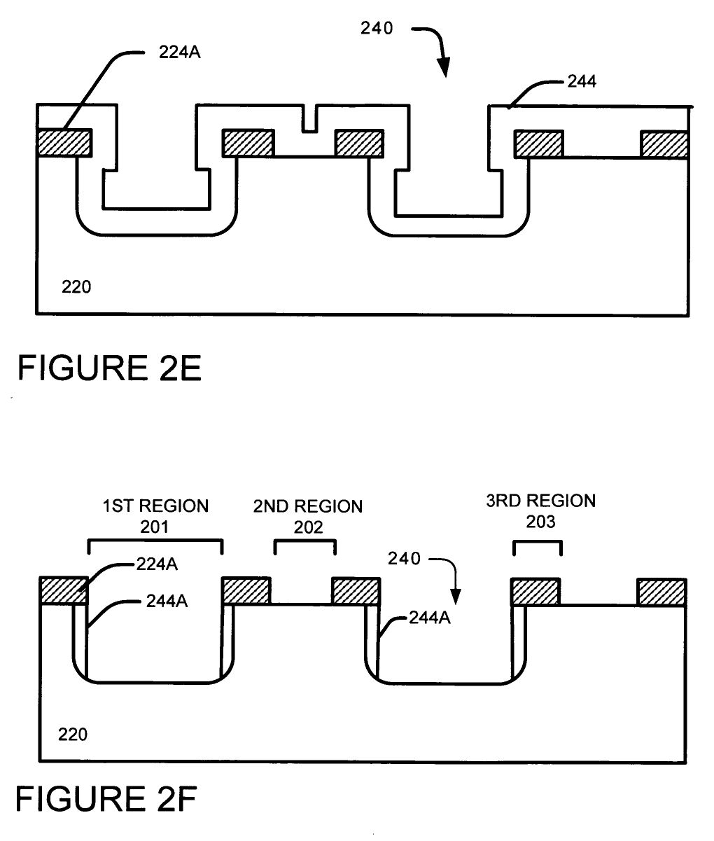

A second example method to form a liner on the sidewalls of the trench of a (single trench) PSM mask is shown in FIGS. 2A to 2F. The second method forms the liner layer over the substrate, trench and opaque layer and then an anisotropic etch is performed. Many of the layers can be formed as described above and the many of the process steps are similar.

Referring to FIG. 2A, a substrate 220 comprised of a transparent material is provided. The substrate has a first thickness. The substrate 220 is comprised of a first region 201, a second region 202, and a third region 203.

Still referring to FIG. 2A, we form an opaque layer 224 over the substrate 220.

A resist pattern 226 is formed over the opaque layer 224. The resist pattern 226 has opening 228 over the first and second regions.

As shown in FIG. 2B, we use a first etch to remove the opaque layer in the first region 201 and the second region 203 to form an opaque pattern 224A over the third region 203.

The resist pattern 226 is removed.

Referring to FIG. 2B, we form a masking pattern 232 having openings 236 over the first region 201.

A. Trench Formation

Referring to FIGS. 2C and 2D, we perform a trench etch to form a trench in the first region 201. The trench has sidewalls and a trench bottom.

The trench etch is preferably comprised of (FIG. 2C) an anisotropic etch and (FIG. 2D) an isotropic etch.

FIG. 2C shows first vertical sidewall trench 239 after the anisotropic etch.

FIG. 2D shows the rounded corner trench 240C on the trench 240 after the isotropic etch. FIG. 2D shows the trench undercut 241.

The isotropic etch forms an undercut 241 that undercuts opaque layer 224A by between 20 and 50 nm.

B. Liner Formation

Referring to FIG. 2E, we remove the masking pattern 232.

Next, we form a lining layer 244 over the substrate, the trench, and the opaque pattern 224A.

As shown in FIG. 2D, the trench has an undercut 241. Preferably, the lining layer has a thickness within 5% of the thickness of the undercut.

The lining layer 244 can have the properties as described above in the first embodiment.

Referring to FIG. 2F, we anisotropically etch the lining layer 244 to form a liner 244A on the sidewalls of the trench 240. The etch chemistry for this most preferably has a high selective between chrome and quartz as the chrome is used as a hard mask during the etching process.

### IV. Example Embodiments for PSM—with Trench Formed Before the Opaque Layer

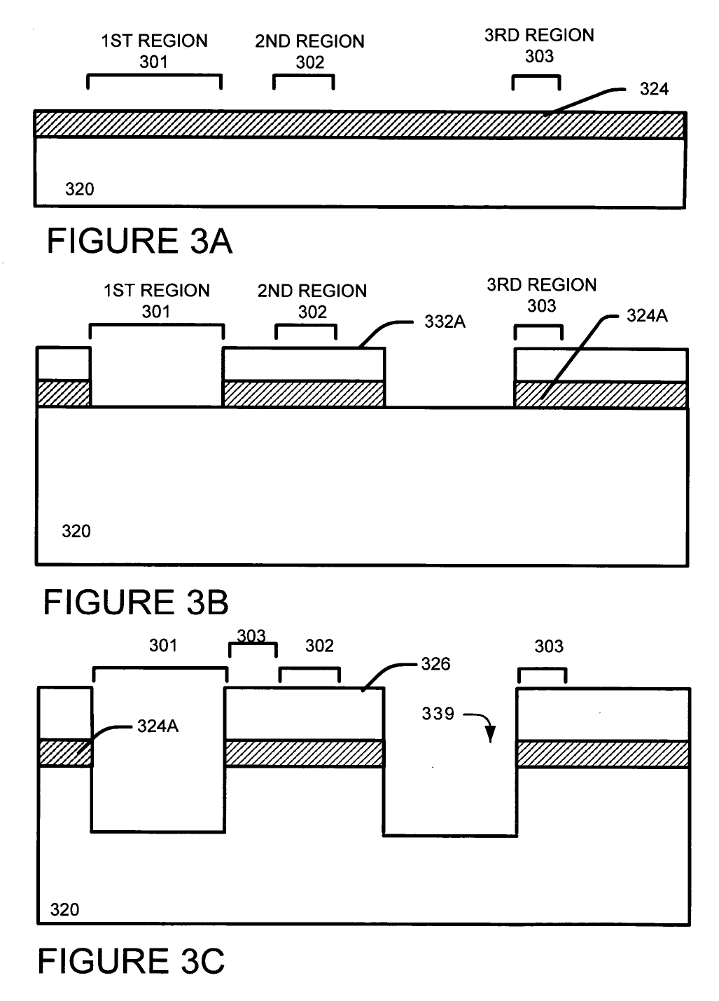

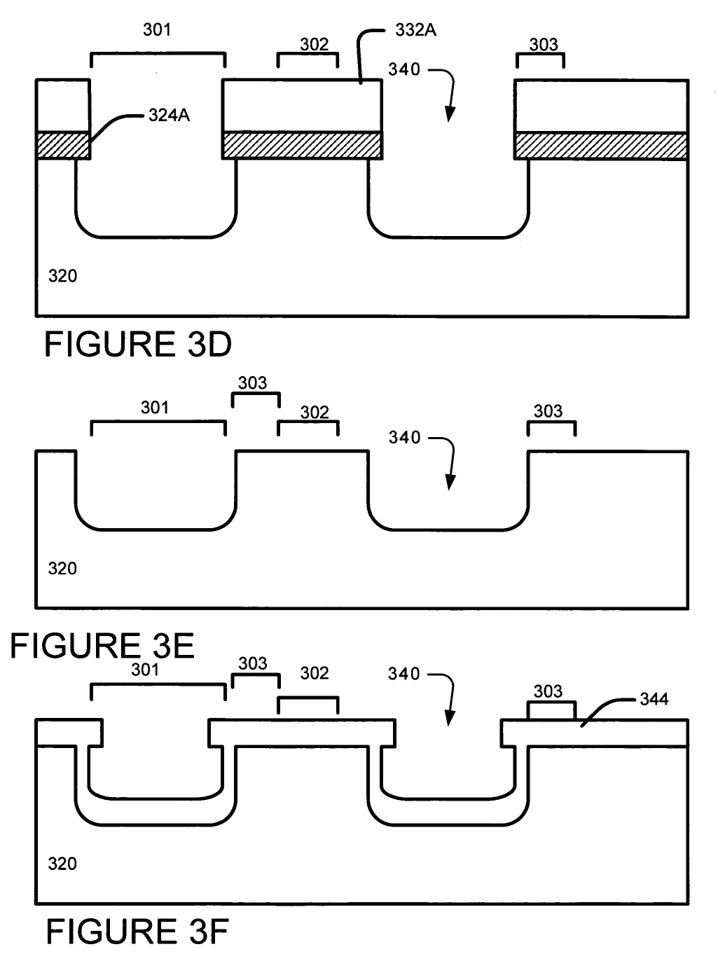

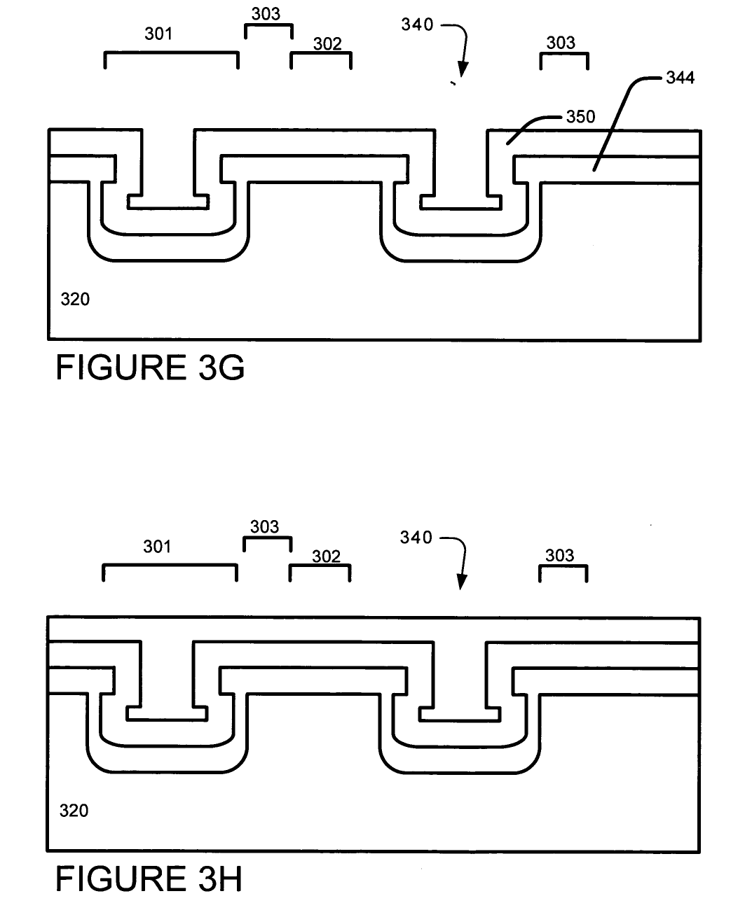

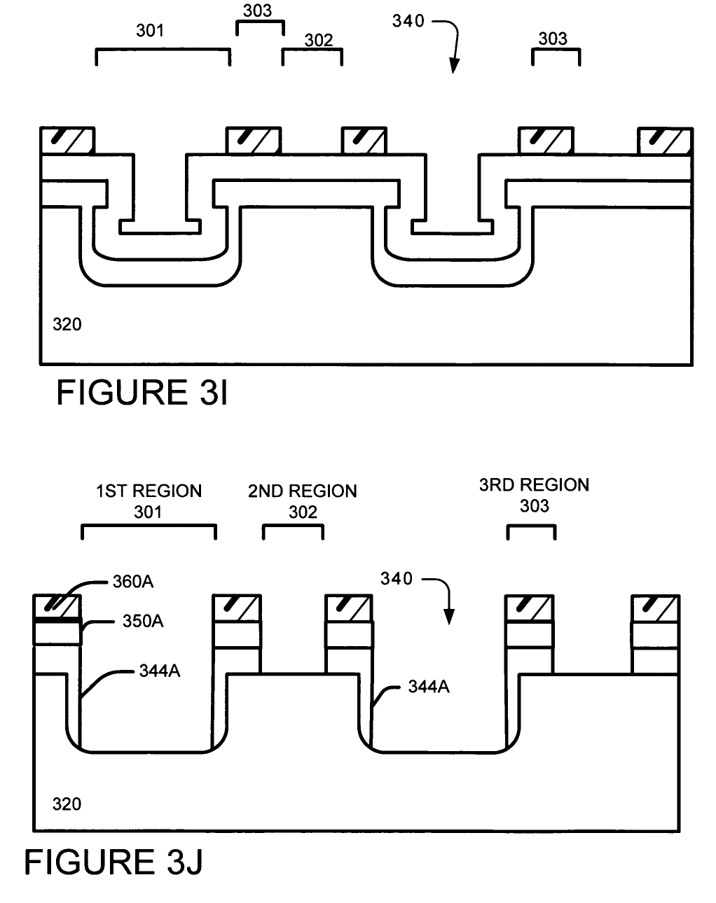

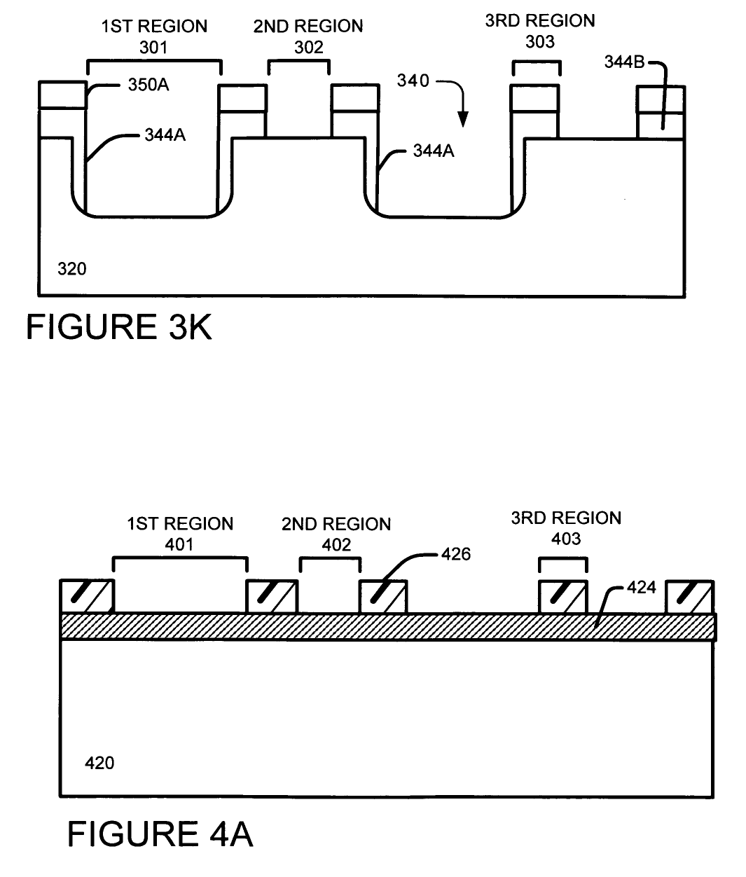

The embodiments' trench liner can also be used on a PSM process where the trench is formed before the chrome layer is deposited. FIGS. 3A to 3K show an example process.

However, the photoresist adhesion to the quartz surface is not as good as to chrome surface, hence the wet etch etchant will react with the quartz underneath the photoresist near the trench at the weak quartz to photoresist interface. This causes unplanar quartz surface near the edges. An alternative process is shown as followed but more processing steps are needed. This method requires the material of the liner to have a good bonding to chrome and quartz.

Many of the layers can be formed as described above and many of the process steps are similar.

As shown in FIG. 3A, a substrate 320 is comprised of a transparent material is provided. The substrate has a first thickness. The substrate 320 comprising a first region 301, a second region 302, and a third region 303. The first region will be a first phase-shifted region. The second region will be a second phase shifted region. Preferably the first phase-shifted region and the second phase shifted region will be about 180 degrees out of phase. The third region will be an opaque region.

As shown in FIG. 3A, we form an first opaque layer 324 or hard mask layer 324 over the substrate 320. The opaque layer is preferably comprised of chrome.

Referring to FIG. 3B, a first masking pattern 332A is formed over the opaque layer 324. The first masking pattern 332A has openings over the first regions 301. The first masking pattern is preferably a resist layer that is patterned using an ebeam or laser write, develop and etch process.

Referring to FIGS. 3C and 3D, trenches 339 340 are formed. As shown in FIG. 3C, we preferably anisotropically etch the chrome 324 and substrate to form chrome patterns 332A and first trenches 339 in the first regions of the mask substrate 320.

As shown in FIG. 3D, we preferably use an isotropic etch to form trenches 340. FIG. 3D shows the rounded corner trench after the isotropic etch.

The isotropic etch preferably undercuts opaque layer 332A by between 20 and 50 nm to form an undercut. The etch and undercut can be performed as described above in the first embodiment.

Referring to FIG. 3E, the resist 332A and opaque layer 324A are removed.

As shown in FIG. 3F, a liner layer 344 is formed over the substrate.

As shown in FIG. 3G, a second opaque layer 350 is formed over the liner layer 344.

As shown in FIG. 3H, a second resist layer 360 is formed over the liner layer 344.

Referring to FIG. 3I, a 2^{nd} mask writing step is performed to form patterns 360A over the third regions 303.

As shown in FIG. 3J, an etch is preformed to remove the second opaque layer and liner layer from over the first and second regions, thus forming opaque patterns 350A, and liner layer patterns 344A. The liner layer patterns 344A are preferably comprised of an upper portion over the top surface of substrate and liners (portion over the sidewalls of the trench 340).

As shown in FIG. 3K, the resist layer is striped.

### V. Example Embodiment for Double PSM

The embodiment's liner spacer is applicable to double trench PSM.

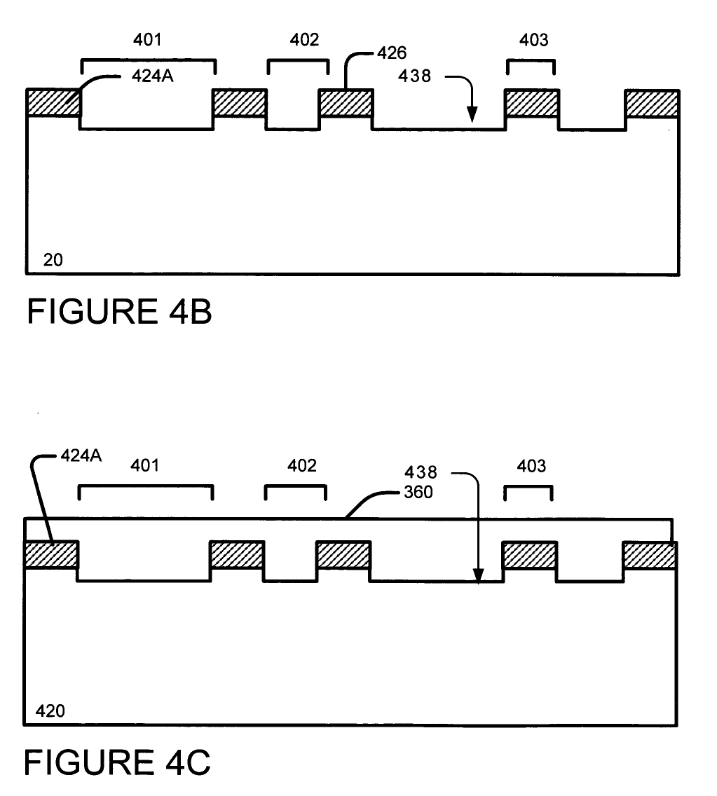

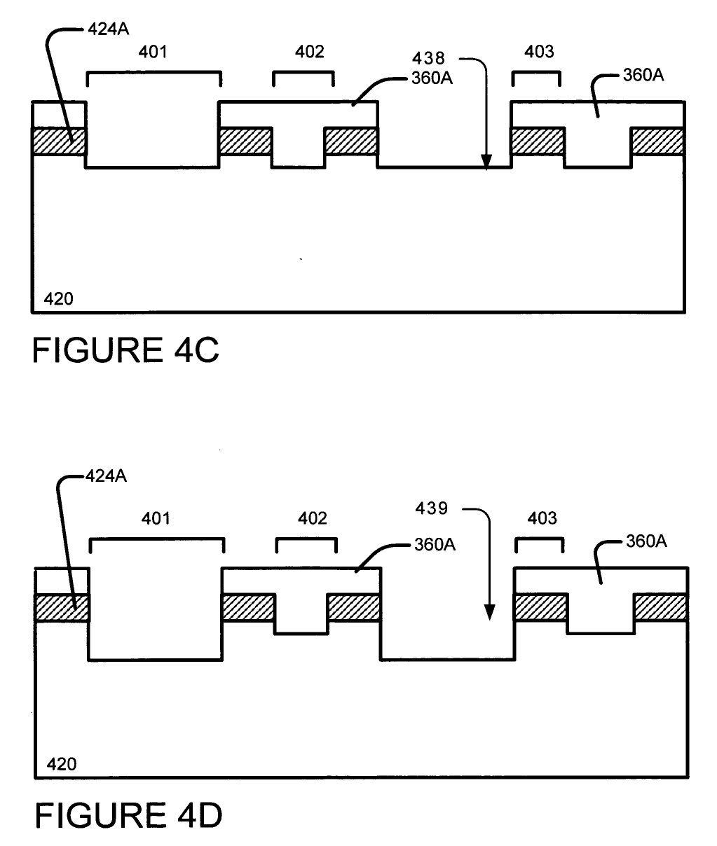

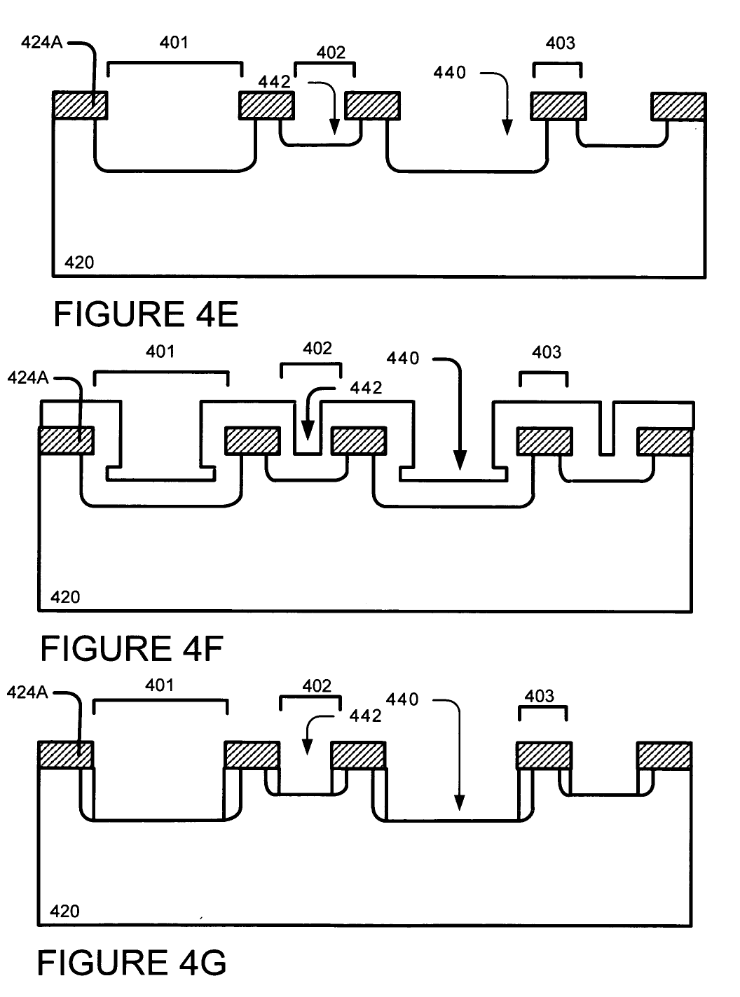

As shown in FIGS. 4A thru 4G, a liner layer 444A 44B can be employed in a double PSM mask.

As shown in FIG. 4A, a substrate 420 comprised of a transparent material is provided. The substrate has a first thickness. The substrate 420 comprising a first region 401, a second region 402, and a third region 403. Preferably the first phase-shifted region and the second phase shifted region will be about 180 degrees out of phase. The third region will be an opaque region.

Referring to FIG. 4A, we form an opaque layer 424 over the substrate 420. The opaque layer is preferably comprised of chrome.

A first resist pattern 426 is formed over the opaque layer and preferably covers the third regions 403.

Referring to FIGS. 4C, 4D, and 4E, trenches 438 and 439 are formed. As shown in FIG. 4C, we etch the chrome 424 and substrate to form chrome patterns 424A and first trenches 439 in the first regions and second regions.

As shown in FIG. 4D, a second resist layer 360 is formed thereover.

As shown in FIG. 4D, the second resist layer 360 is patterned to form second pattern 360A. Trench 439 is etch in the first regions 401.

As shown in FIG. 4E, the second resist is preferably removed.

As shown in FIG. 4E, we preferably use an isotropic etch to etch the trenchs 442 440. FIG. 4E shows the rounded corner in trenches 440 442 after the isotropic etch.

As shown in FIG. 4F, a liner layer 444 is formed over the surface.

As shown in FIG. 4G, preferably an anisotropic etch is performed to for liners 444A and 444B in the trenches 440 and 442.

A. Retrograde Trench Profile

The embodiment's trench can have a “retrograde profile” (see e.g., shown in U.S. Pat. No. 6,458,495 to Tsai et al.). By having a retrograde profile and the sidewall liner, the stray lights could be further controlled but the cost and difficulty of making this type of mask increases.

### VI. Embodiments for (CPL) Chromeless Phase Lithography Masks

The liners of the embodiments can be employed on a different type of strong phase shift mask, such as CPL or CPL (Chromeless Phase Lithography mask) with Chrome patch.

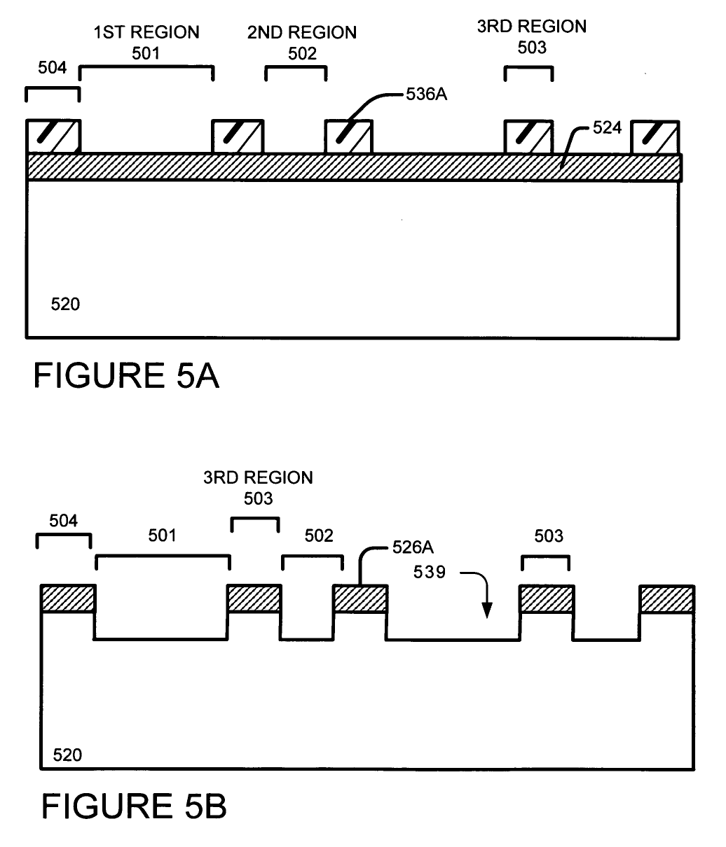

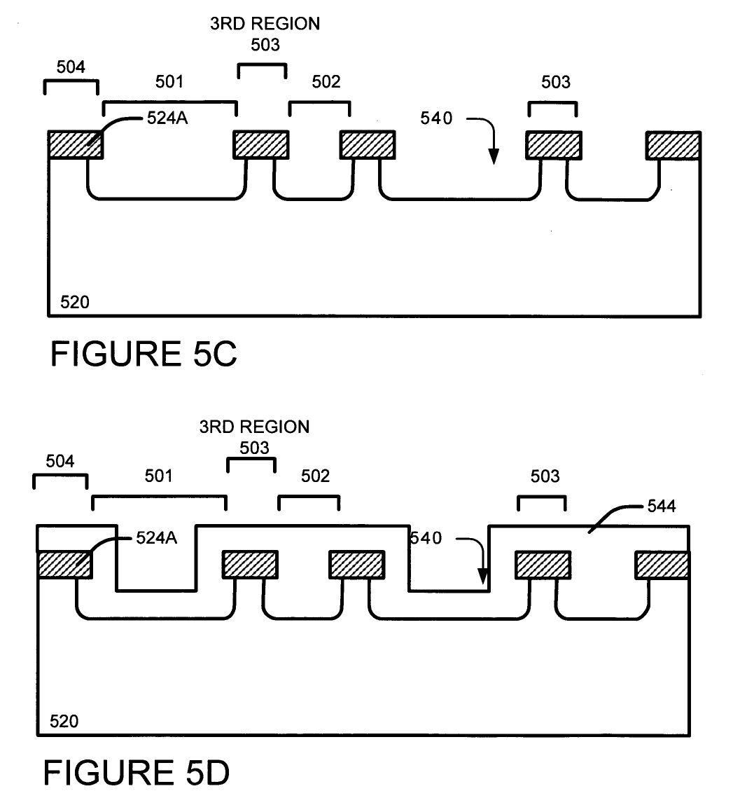

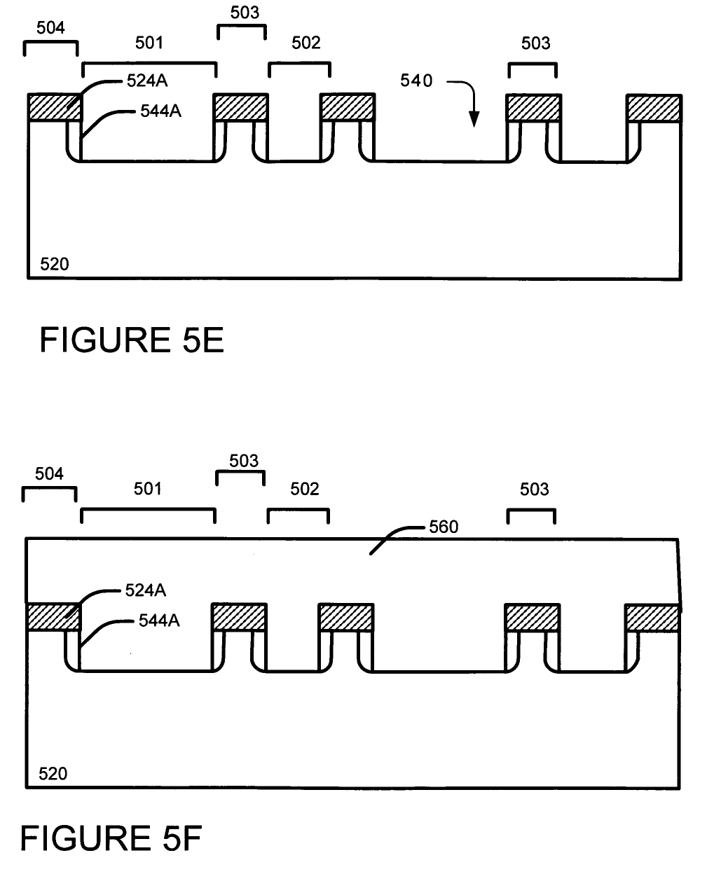

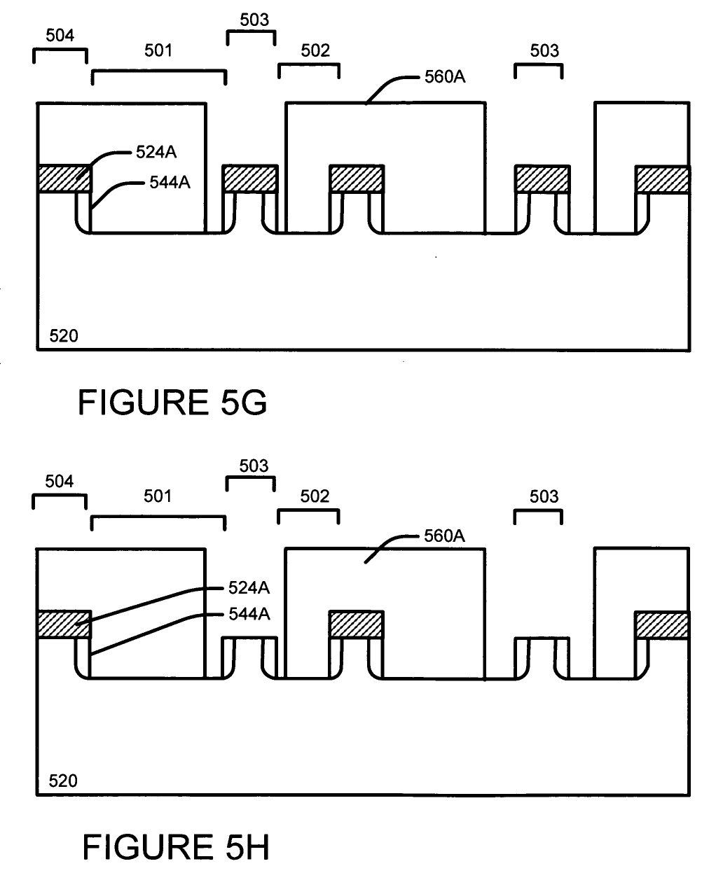

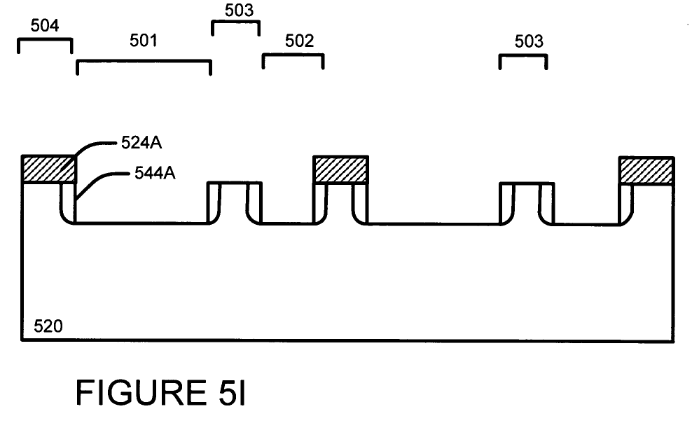

As shown in FIGS. 5A thru 5I, the liners of the embodiments can be employed a Chromeless Phase Lithography mask with a Chrome patch.

As shown in FIG. 5A, a substrate 520 comprised of a transparent material is provided. The substrate has a first thickness. The substrate 320 comprising a first region 501, a second region 502, a third region 503 and a fourth region 504. The first region will be a phase-shifted region, such as a 180 degree phase shift region. The second region will be a second phase shifted region (such as a 180 degree phase shift). The third region will be an transparent non-shifted region and the forth region is preferably an opaque region.

Referring to FIG. 5A, we form an opaque layer 524 over the substrate 520. The opaque layer is preferably comprised of chrome. A mask pattern 536A is formed over the opaque layer.

Referring to FIGS. 5B, 5C, and 5D trenches 539 and 540 are formed. As shown in FIG. 5B, we etch the chrome 524 and substrate to form chrome patterns 524A and first trenches 439 in the first regions and second regions.

As shown in FIG. 5B, the resist layer 536A is removed.

As shown in FIG. 5C, using the chrome patterns 524A as mask, we form second (undercut) trenches 540 in the first regions and second regions. we preferably use an isotropic etch to achieve the undercut.

As shown in FIG. 5D, a liner layer 544 is formed over the surface.

As shown in FIG. 4E, preferably an anisotropic etch is performed to for liners 544A in the trenches 540.

As shown in FIG. 5F, we form a second photoresist layer 560 over the surface.

As shown in FIG. 5G, the second photoresist layer 560A is patterned to form patterns 560A with openings over the third region 503.

As shown in FIG. 5H, the opaque layer 524A is removed over the third regions 503.

As shown in FIG. 5I, the second resist is removed to form a CLP mask with chrome patches and liners 544A.

### VII. Other Options

If desired, one or more layers may be included between the transparent substrate and the overlying opaque layer. Such intermediate layers may serve to modify the aerial image during exposure of a wafer through the mask in a wafer stepper. For example, Molybdenum Silicide (MoSi or MoSiON) or Fluorine-containing chrome (CrFO) may be used for the shifter material in an attenuated embedded PSM (AttEPSM).

The intermediate layers may also help in the fabrication of the mask, such as to serve as an etch stop to control thickness of the transparent substrate or of any shifter material. If desired, the intermediate layers may subsequently be removed from the light path in the clear openings and only retained underneath the opaque layer.

Corresponding elements in the embodiments can be formed as described in the other embodiments. Descriptions and parameters have not been repeated.

In the above description numerous specific details are set forth such as flow rates, pressure settings, thicknesses, etc., in order to provide a more thorough understanding of the present invention. It will be obvious, however, to one skilled in the art that the present invention may be practiced without these details. In other instances, well known process have not been described in detail in order to not unnecessarily obscure the present invention.

Although this invention has been described relative to specific insulating materials, conductive materials and apparatuses for depositing and etching these materials, it is not limited to the specific materials or apparatuses but only to their specific characteristics, such as conformal and nonconformal, and capabilities, such as depositing and etching, and other materials and apparatus can be substituted as is well understood by those skilled in the microelectronics arts after appreciating the present invention

While the invention has been particularly shown and described with reference to the preferred embodiments thereof, it will be understood by those skilled in the art that various changes in form and details may be made without departing from the spirit and scope of the invention. It is intended to cover various modifications and similar arrangements and procedures, and the scope of the appended claims therefore should be accorded the broadest interpretation so as to encompass all such modifications and similar arrangements and procedures.

What is claimed is:

1. A method of fabricating a phase-shifting mask for use with a light at a wavelength comprising:
a) providing a substrate comprised of a transparent material, said substrate comprising a first region, a second region, and a third region,
b) forming an opaque pattern over said third region of said substrate;
c) using a trench etch to form a first trench in said first region, said trench having sidewalls and a trench bottom; said first trench extends a first undercut distance under said opaque pattern;
d) forming a liner over the sidewalls of said first trench;
whereby said light at said wavelength transmitted through said first region is shifted in phase by 180 degrees relative to said light at said wavelength transmitted through said second region;
whereby said liner reduces reflection from the trench sidewalls.

2. The method of claim 1 wherein said liner is only on the sidewalls of said first trench;
said liner is not over the trench bottom and is not over the opaque pattern.

3. The method of claim 1 which further comprises forming a second trench in said second region;
said second trench extends a second undercut distance under said opaque pattern in said third region;
said second trench has said second trench has said liner formed the sidewalls of second trench.

4. The method of claim 1 wherein said first trench extends a first undercut distance under said opaque pattern between 20 and 50 nm.

5. The method of claim 1 wherein said first trench extends a first undercut distance under said opaque pattern about equal or less than 50% of the minimum width of the opaque pattern.

6. The method of claim 1 wherein said lining layer is comprised of a material with an extinction coefficient between about 1.0 and 3.0.

7. The method of claim 1 wherein said liner is comprised of a material with a reflective index between 1.4 and 1.6.

8. The method of claim 1 wherein said liner is comprised of a material with a reflective index within 5% of the reflective index of quartz.

9. The method of claim 1 wherein said liner comprised of a materials with an etch selective to chromium of between 0.01 and 0.1, and an etch selective to quartz of between 0.01 and 0.1.

10. The method of claim 1 wherein said liner is comprised a material selected from the group consisting of metal oxides, metal nitrate, and aluminum oxide.

11. A method of fabricating a phase-shifting mask for use with a light at a wavelength comprising:
a) providing a substrate comprised of a transparent material, said substrate having a first thickness, said substrate comprising a first region, a second region, and a third region,
b) forming an opaque layer over said substrate,
c) etching in a first etch to remove said opaque layer in said first region and said second region to form a opaque pattern on the third region,
d) forming a masking pattern having openings over said first region;
e) etching said substrate in a trench etch to form a first trench in said first region, said trench having sidewalls and a trench bottom; said first trench extends a first undercut distance under said opaque pattern;
f) forming a lining layer over said masking pattern and said trench;
g) anisotropically etching said lining layer to form a liner on the sidewalls of said trench;
h) removing said masking pattern; whereby said light at said wavelength transmitted through said first region is shifted in phase by 180 degrees relative to said light at said wavelength transmitted through said second region;
whereby said liner reduces reflection from the trench sidewalls.

12. The method of claim 11 wherein said trench etch is comprised of an anisotropic etch and an isotropic etch.

13. The method of claim 11 wherein said first trench extends under said opaque pattern in said third region by between 20 and 50 nm.

14. The method of claim 11 wherein said first trench extends a first undercut distance under said opaque pattern about equal or less than 50% of the minimum width of the opaque pattern.

15. The method of claim 11 wherein said lining layer is comprised of a material with an extinction coefficient between about 1.0 and 3.0.

16. The method of claim 11 wherein said liner is comprised of a material with a reflective index within 5% of the reflective index of quartz.

17. The method of claim 11 wherein said liner comprised of a materials with an etch selective to chromium of between 0.01 and 0.1, and an etch selective to quartz of between 0.01 and 0.1.

18. The method of claim 11 wherein said liner is comprised a material selected from the group consisting of metal oxides, metal nitrate, and aluminum oxide.

19. A method of fabricating a phase-shifting mask for use with a light at a wavelength comprising:
a) providing a substrate comprised of a transparent material, said substrate having a first thickness, said substrate comprising a first 3 region, a second region, and a third region;
b) forming an opaque layer over said substrate;
c) using a first etch to remove said opaque layer in said first region and said second region to form an opaque pattern over said third region;
d) forming a masking pattern having openings over said first region;
e) using a trench etch to form a trench in said first region, said trench having sidewalls and a trench bottom;
(1) said trench etch is comprised of an anisotropic etch and an isotropic etch;
said isotropic etch undercuts opaque layer by between 20 and 50 nm;
f) removing said masking pattern;
g) forming a lining layer over said substrate, said trench, and said opaque pattern;
h) anisotropically etching said lining layer to form a liner on the sidewalls of said trench;
whereby said light at said wavelength transmitted through said first region is shifted in phase by 180 degrees relative to said light at said wavelength transmitted through said second region.

20. The method of claim 19 wherein said trench has an undercut; said lining layer has a thickness within 5% of the thickness of said undercut.

21. The method of claim 19 wherein said lining layer is comprised of a materials that can be deposited with high extinction coefficient between about 1.0 and 3.0.

22. The method of claim 19 wherein said lining layer is comprised of a material with a reflective index between 1.4 and 1.6.

23. The method of claim 19 wherein said lining layer is comprised of a material with a reflective index within 5% of the reflective index of quartz.

24. The method of claim 19 wherein said lining layer is comprised of a materials with etch selective between chromium and quartz of between 0.01 and 0.1.

25. The method of claim 19 wherein said lining layer is comprised of a material selected from the group consisting of metal oxides, metal nitrate, and aluminum oxide.

26. A method of fabricating a phase-shifting mask for use with a light at a wavelength comprising:
a) providing a substrate comprised of a transparent material, said substrate comprising a first region, a second region, and a third region,
b) forming a first trench in said first region, said trench having sidewalls and a trench bottom; said first trench extends a first undercut distance under said opaque pattern;
c) forming a liner layer over said substrate;
d) forming an opaque layer over said liner layer;
e) patterning said liner layer and said opaque layer to form (a) a liner pattern only on the sidewalls of said first trench and over the third region; said liner is not on the trench bottom; and to form (b) a opaque pattern over the liner patterns in said third regions;
whereby said light at said wavelength transmitted through said first region is shifted in phase by 180 degrees relative to said light at said wavelength transmitted through said second region;
whereby said liner reduces reflection from the first trench sidewalls.

27. The method of claim 26 wherein said first trench extends a first undercut distance under said opaque pattern about equal or less than 50% of the minimum width of the opaque pattern.

28. A method of fabricating a double trench phase-shifting mask for use with a light at a wavelength comprising:
a) providing a substrate comprised of a transparent material, said substrate comprising a first region, a second region, and a third region,
b) forming an opaque pattern over said third region of said substrate,
c) using a trench etch to form a first region trench in said first region and a second region trench in said second region, said first region trench and said second region trench having sidewalls and a trench bottom; the first and second region trench extend a first undercut distance under said opaque pattern in the third region;
d) forming a liner only on the sidewalls of said first trench;
said liner is not on the trench bottom and is not over the opaque pattern;
whereby said light at said wavelength transmitted through said first region is shifted in phase by 180 degrees relative to said light at said wavelength transmitted through said second region;
whereby said liner reduces reflection from the trench sidewalls.

29. The method of claim 28 wherein the first undercut distance is about equal or less than 50% of the minimum width of the opaque pattern.

30. A method of fabricating a chromeless Phase Lithography mask with chrome patch for use with a light at a wavelength comprising:
a) providing a substrate comprised of a transparent material, said substrate, said substrate comprising a first region, a second region, and a third region and a fourth region, the first region will be a phase-shifted region, the second region will be a second phase shifted region, the third region will be an transparent non-shifted region and the forth region will be an opaque region;
b) forming an opaque pattern over said third region of said substrate,
c) using a trench etch to form a first region trench in said first region and a second region trench in said second region, said first region trench and said second region trench having sidewalls and a trench bottom; the first and second region trench extend a first undercut distance under said opaque pattern in the third region and fourth region;
d) forming a liner over the sidewalls of said first region and said second region trench;
e) removing the opaque pattern over the third regions;
f) whereby said light at said wavelength transmitted through said first and second regions is shifted in phase by 180 degrees relative to said light at said wavelength transmitted through said third region;
whereby said liner reduces reflection from the trench sidewalls.
g) forming a liner only over the sidewalls of said first region and said second region trench;

31. The method of claim 30 wherein liner is only over the sidewalls of said first region and said second region trench; said liner is not on the trench bottom and is not over the opaque pattern.

32. The method of claim 30 wherein said first trench extends a first undercut distance under said opaque pattern about equal or less than 50% of the minimum width of the opaque pattern.

33. A phase-shifting mask for use with light at a wavelength comprising:
a substrate,
a first region located on said substrate, a first region trench in said first region; a liner on the sidewalls of said first region trench; said first region having a first thickness, said first region having a first amount of transmission of light at said wavelength,
a second region located on said substrate, said second region having a second thickness, such that said second thickness is greater than said first thickness by a first difference, said first difference being equivalent to a phase shift of 180 degrees at said wavelength, and
a third region located on said substrate, said third region having a third thickness, such that said third thickness is equal to or greater than said second thickness;
an opaque pattern over said third region; said opaque pattern opaque to light at said wavelength;
a liner on the sidewalls of said first region trench; said liner is not on the trench bottom of said first region trench and is not over the opaque pattern.

34. The phase-shifting mask of claim 33 further having a second region trench in said second region; a liner on the sidewalls of said second region trench; said second region trench is under said opaque pattern by a undercut distance.

35. The phase-shifting mask of claim 33 further having a second region trench in said second region; a liner on the sidewalls of said second region trench; said second region trench is under said opaque pattern by an undercut distance between 20 and 50 nm.

36. The phase-shifting mask of claim 33 wherein said first trench extends a first undercut distance under said opaque pattern about equal or less than 50% of the minimum width of the opaque pattern.

37. The phase-shifting mask of claim 33 wherein said first region trench is under said opaque pattern by a first undercut distance.

38. The phase-shifting mask of claim 33 wherein said first region trench extends a first undercut distance under said opaque pattern between 20 and 50 nm.

39. The phase-shifting mask of claim 33 wherein said liner is comprised of a material with an extinction coefficient between about 1.0 and 3.0.

40. The phase-shifting mask of claim 33 wherein said liner is comprised of a material with a reflective index between 1.4 and 1.6.

41. The phase-shifting mask of claim 33 wherein said liner is comprised of a material with a reflective index within 5% of the reflective index of quartz.

42. The phase-shifting mask of claim 33 wherein said liner is comprised of a materials with an etch selective to chromium of between 0.01 and 0.1, and an etch selective to quartz of between 0.01 and 0.1.

43. The phase-shifting mask of claim 33 wherein said liner is comprised a material selected from the group consisting of metal oxides, metal nitrate, and aluminum oxide.

44. A chromeless phase lithography mask with a opaque patch for use with light at a wavelength comprising:
a substrate having a first region, a second region, a third region, and forth region;
a first region trench in said first region and a second region trench in said second region; a first region and said second region having a first thickness of a first material, said first material having a first amount of transmission of light at said wavelength,
said third region and said fourth having a second thickness of said first material, such that said second thickness is greater than said first thickness by a first difference, said first difference being equivalent to a phase shift of 180 degrees at said wavelength, and
an opaque pattern over said fourth region;
a liner over the sidewalls of said first region trench and said second region trench.

45. The chromeless phase lithography mask with a chrome patch of claim 44 wherein said first region trench and said second region trench extend into said third and said fourth regions by a first undercut distance.

46. The chromeless phase lithography mask with a chrome patch of claim 44 wherein said first region trench and said second region trench extend into said third and said fourth regions by a first undercut distance between 20 and 50 nm.

47. The chromeless phase lithography mask with a chrome patch of claim 44 wherein said first region trench and said second region trench extend into said third and said fourth regions by a first undercut distance about equal or less than 50% of the minimum width of the opaque pattern.

48. The chromeless phase lithography mask with a chrome patch of claim 44 wherein said liner is comprised of a material with an extinction coefficient between about 1.0 and 3.0.

49. The chromeless phase lithography mask with a chrome patch of claim 44 wherein said liner is comprised of a material with a reflective index between 1.4 and 1.6.

50. The chromeless phase lithography mask with a chrome patch of claim 44 wherein said liner is comprised of a material with a reflective index within 5% of the reflective index of quartz.

51. The chromeless phase lithography mask with a chrome patch of claim 44 wherein said liner is comprised of a materials with an etch selective to chromium of between 0.01 and 0.1, and an etch selective to quartz of between 0.01 and 0.1.

52. The chromeless phase lithography mask with a chrome patch of claim x wherein is comprised a material selected from the group consisting of metal oxides, metal nitrate, and aluminum oxide
